(19) United States
(12) Patent Application Publication
(10) Pub. No.: US 2005/0181533 A1
(43) Pub. Date: Aug. 18, 2005

(54) Method for manufacturing an electro-optical device board, optical device, electro-optical device and electronic equipment

(75) Inventors: Takeo Kawase, Suwa-shi (JP); Soichi Moriya, Chino-shi (JP); Mitsuaki Harada, Chino-shi (JP)

Correspondence Address: BANNER & WITCOFF, 1001 G STREET N W, SUITE 1100, WASHINGTON, DC, 20001, US

(73) Assignee: Seiko Epson Corporation, Shinjuku-ku (JP)

(21) Appl. No.: 11/045,189

(22) Filed: Jan. 31, 2005

(30) Foreign Application Priority Data
Feb. 2, 2004 (JP) 2004-25446

(51) Int. Cl. H01L 21/00

(52) U.S. Cl. 438/82

(57) ABSTRACT

A method for manufacturing an electro-optical device board including on a substrate a switching element and a coupling wiring coupled to the switching element is provided. The method includes the steps of forming the switching element and first coupling wirings simultaneously by patterning using light irradiation; and forming second coupling wirings by an additive patterning process.

### RELATED APPLICATION

This application claims priority to Japanese Application No. 2004-25446, filed Feb. 2, 2004, whose contents are explicitly incorporated herein by reference.

### TECHNICAL FIELD

Aspects of the present invention relate to a method for manufacturing optical device, an electro-optical device board, an electro-optical device and electronic equipment.

### BACKGROUND

In recent years, methods for manufacturing an organic transistor using vapor deposition, photolithography, and etching techniques in combination have been proposed. According to such methods, a metal film is formed by vapor deposition and processed by photolithography, so as to make a gate electrode and source and drain electrodes. Also, an insulating layer and an organic semiconductor layer are thinly formed by vapor deposition as described in Japanese Unexamined Patent Publication No. 5-55568. This manufacturing method can provide a high-performance organic transistor element with high reproducibility. The technique described in Japanese Unexamined Patent Publication No. 5-55568., however, requires a vacuum device, which increases cost to manufacture an organic transistor.

More recently, methods for manufacturing a gate electrode, source and drain electrodes, an insulating layer, and an organic semiconductor layer by solution processing at atmospheric pressure have been developed as described in PCT Application No. 2003-518756. and PCT Application No. 2003-518754, for example. According to such methods, a conductive polymer solution is printed by an inkjet (droplet discharge) method, for example, so as to make a gate electrode and source and drain electrodes. Accordingly, the method provides a device at low cost.

The inkjet processes disclosed in PCT Application No. 2003-518756. and PCT Application No. 2003-518754, however, deliver far less resolution than photolithography, and provide sufficiently high-speed drawing only when line widths are 10 μm or more. Therefore, if all electrodes and other conductive parts are made by ink jetting, the width of wirings becomes so large that it is difficult to increase packaging density.

In addition, an electronic device, such as a display, having an organic transistor requires driver circuits provided on two sides in both the X and Y directions of its substrate. These driver circuits decrease the layout flexibility of the electronic device. In order to mount the driver circuits aggregately on one side, wirings coupled to X and Y drivers need to be formed on one side. In this case, however, there arises another problem of limited resolution provided by wirings made by ink jetting, which makes it difficult to aggregate these wirings on one side. Furthermore, using ink jetting to provide a complicated wiring pattern requires an inkjet head to scan repeatedly, which may severely reduce productivity.

### SUMMARY OF THE INVENTION

In consideration of the above-mentioned problems, the present invention aims to provide a method for manufacturing an electro-optical device board at low cost, low temperature, and low energy by ink jetting, while providing highly fine wirings coupled to an organic transistor. The present invention also aims to provide an electro-optical device board manufactured by the manufacturing method. Furthermore, the present invention aims to provide an electro-optical device having the electro-optical device board, and electronic equipment having the electro-optical device.

In order to address the above-mentioned problems, the present invention has the following aspects.

A method for manufacturing an electro-optical device board according to the present invention provides an electro-optical device board that includes, on a substrate, a switching element and a coupling wiring coupled to the switching element. The manufacturing method includes the following steps: forming the switching element and a first coupling wiring simultaneously by patterning using light irradiation; and forming a second connection line by an additive patterning process.

According to one aspect, the switching element refers to thin film transistor (TFT) and thin film diode (TFD) elements, and the like. Also, the patterning using light irradiation can be carried out by a photolithography process or by the irradiation of light having chemical action, such as ultraviolet rays.

As such, the first coupling wiring can be formed by patterning using light irradiation on the substrate, providing highly fine patterns. Since the patterning is carried out using light irradiation, highly fine patterns of wavelength resolution can be achieved. Also, since the switching element and the first coupling wiring are formed simultaneously by patterning using light irradiation, the manufacturing steps can be simplified. Furthermore, since the second coupling wiring is formed by an additive patterning process, patterns can be provided directly on the substrate. Therefore, film-forming and removal steps, which are involved in patterning by light irradiation, are not required, and thus the second coupling wiring can be provided easily.

The additive patterning process can be an inkjet (droplet discharge) process, which imposes no heat load on the substrate. According to aspects of the invention, in the series of steps for forming the switching element, the first coupling wiring and the second coupling wiring, it is possible to minimize steps that impose a heat load on the substrate, for example a film-forming step. Therefore, if the substrate is made of a plastic material, the risk of thermal expansion, buckling, and other deformation of the substrate caused by such a heat load can be reduced. In other words, in certain aspects of the invention, the method for manufacturing an electro-optical device board can achieve low-cost, low-temperature, and low-energy manufacturing. The method can be particularly beneficial for manufacturing a flexible device.

In the method for manufacturing an electro-optical device board, a lower electrode of the switching element and the first coupling wiring may be formed simultaneously. In one aspect, the lower electrode of the switching element is a member that is firstly formed on the substrate in the switching element. Accordingly, in this aspect the lower electrode can be formed simultaneously with the first coupling wiring that is firstly formed on the substrate.

In the method for manufacturing an electro-optical device board, the second coupling wiring and a gate electrode of the switching element may be formed simultaneously. In one aspect, the gate electrode of the switching element is a member that is formed in the uppermost part of the switching element. Accordingly, the gate electrode formed in the uppermost part in the switching element can be formed simultaneously with the second coupling wiring.

In the method for manufacturing an electro-optical device board, the lower electrode may include source and drain electrodes. In one aspect the source and drain electrodes are formed on the substrate side, and an insulating film and the gate electrode are formed on top of that, which forms a top-emission transistor.

In the method for manufacturing an electro-optical device board, a semiconductor layer of the switching element may be an organic semiconductor layer. As such a switching element can be provided.

In the method for manufacturing an electro-optical device board, the organic semiconductor layer may be a polymer mainly containing arylamine. As such an organic semiconductor layer can be provided.

In the method for manufacturing an electro-optical device board, the organic semiconductor layer may be a copolymer mainly containing fluorene-bithiophene. As such an organic semiconductor layer can be provided.

In the method for manufacturing an electro-optical device board, the organic semiconductor layer may be formed by an inkjet process. In one aspect, a droplet discharge process can be used for forming the organic semiconductor layer. The droplet discharge process can reduce facility cost and the number of materials and steps required, and thereby provide an electro-optical device board at low cost.

In the method for manufacturing an electro-optical device board, the first coupling wiring may be aggregated on one side of the substrate. In one aspect, the first coupling wiring is formed by patterning using light irradiation, and it can be easily aggregated. If the first coupling wiring is formed by ink jetting, limited patterning resolution and multiple scans by an inkjet head can result in decreased productivity. By patterning using light irradiation for forming the first coupling wiring, these problems can be solved.

In one aspect of the invention the method for manufacturing an electro-optical device board, the first coupling wiring, which is aggregated, may be coupled to an integrated circuit. By coupling the first coupling wiring aggregated on one side of the substrate to the integrated circuit, there is no need for forming the integrated circuit on two sides. This increases the layout flexibility of an electronic device having the electro-optical device board.

In the method for manufacturing an electro-optical device board, widths of the first and second coupling wirings and a gap between the first and second coupling wirings may be 10 μm or less. In this aspect, the manufacturing method provides an electro-optical device board with fine wiring pitches.

In the method for manufacturing an electro-optical device board, widths of the first and second coupling wirings and a gap between the first and second coupling wirings may be 6 μm or less. In this aspect, the manufacturing method provides an electro-optical device board with fine wiring pitches.

In the method for manufacturing an electro-optical device board, the substrate may be a plastic substrate. In this aspect, the manufacturing method provides a flexible electro-optical device board.

An electro-optical device board according to the present invention can be manufactured by any of the above-mentioned manufacturing methods. As such the electro-optical device board can have the above-mentioned effects.

An electro-optical device according to certain aspects of the present invention includes: the above-mentioned electro-optical device board; an opposing substrate placed face to face with the electro-optical device board; and an electro-optical layer provided between the electro-optical device board and the opposing substrate. In at least certain aspects the electro-optical device can be manufactured at low cost, low temperature, and low energy. Furthermore, a flexible electro-optical device can be provided.

Electronic equipment according to the present invention includes the above-mentioned electro-optical device. In at least certain aspects the electronic equipment can be manufactured at low cost, low temperature, and low energy. Furthermore, flexible electronic equipment can be provided.

### BRIEF DESCRIPTION OF THE DRAWINGS

FIG. 1A is a plane view of an illustrative electro-optical device board according to the present invention, and FIG. 1B is a sectional view showing an electro-optical device board according to the present invention.

FIGS. 2A-2H show an illustrative structure at various stages in the performance of a method for manufacturing an electro-optical device board according to the present invention.

FIGS. 3A-3D show an illustrative structure at various stages in the performance of the method for manufacturing an electro-optical device board according to the present invention.

FIG. 4 shows an illustrative structure at a stage in the performance of the method for manufacturing an electro-optical device board according to the present invention.

FIG. 5 shows an illustrative structure at a stage in the performance of the method for manufacturing an electro-optical device board according to the present invention.

FIG. 6 shows an illustrative structure at a stage in the performance of the method for manufacturing an electro-optical device board according to the present invention.

FIG. 7 shows an example of an electro-optical device according to the present invention.

FIG. 8 shows an example of electronic equipment according to the present invention.

FIG. 9 shows another example of electronic equipment according to the present invention.

### DETAILED DESCRIPTION

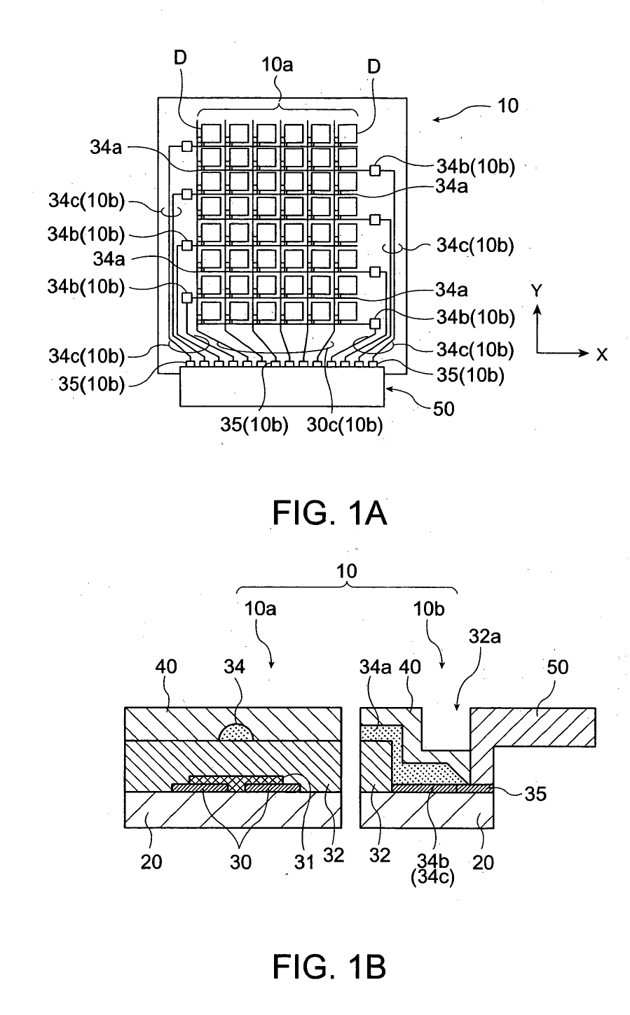

Referring to FIGS. 1 through 9, a method for manufacturing an electro-optical device board, an electro-optical device board, an electro-optical device, and electronic equipment according to the present invention will be described. Embodiments of the present invention are shown by way of example, and not intended to limit the present invention. It is understood that various modifications can be made without departing from the spirit and scope of the present invention. In the accompanying drawings, the scale of each layer and each member is adequately changed, so that they are visible.

First, the structure of an electro-optical device board according to embodiments of the invention will be described referring to FIGS. 1A and 1B. FIG. 1A is a plane view of the electro-optical device board, and FIG. 1B is a sectional view of the electro-optical device board showing its major components. Referring to FIG. 1A, an electro-optical device board 10 is provided with a plurality of organic transistors (switching element) 10a, a plurality of gate lines (second connection wirings) 34a, and a plurality of pixel electrodes D on the central part of a substrate 20; and a gate line connection part (first connection wiring) 34b, a gate line lead (first connection wiring) 34c, a source line lead (first connection wiring) 30c, and an external connection part (first connection wiring) 35 on an outer periphery 10b of the substrate 20.

Each of the components will now be described.

The substrate 20 may be made of various materials irrespective of their transparency and transmittance. Here, a plastic substrate that is flexible is used in the present embodiment. The organic transistor 10a is a switching element formed mainly by a wet film-forming method as described in greater detail below. The organic transistor 10a has a top-gate structure in which source and drain electrodes, an insulating layer, and a gate electrode are stacked on the substrate 20 in this order. While the top-gate structure is used in the present embodiment, the structure of transistors to which the present invention can be applied is not so limited. Bottom-gate transistors can also be used. The gate line 34a is a wiring extending in the X direction in FIG. 1A. The gate line 34a couples a gate electrode 34 (shown in FIG. 1B) to the gate line connection part 34b. The gate line 34a is a wiring formed by an inkjet (additive patterning) method. The gate line connection part 34b is a terminal that couples the gate line 34a to the gate line lead 34c as a relay point, and is formed by a vapor film-forming method on the substrate 20. The gate line connection part 34b is formed at the same as the source and drain electrodes and the external connection part 35. The gate line lead 34c is a wiring coupling the gate line connection part 34b to the external connection part 35, and is aggregated with highly fine line widths. The external connection part 35 is a terminal coupling the electro-optical device board 10 to a flexible printed circuit (FPC) 50. The FPC 50 is a circuit board mainly composed of a driver circuit (integrated circuit) for driving the organic transistor 10a of the electro-optical device board 10. The FPC 50 supplies power to the source line of the electro-optical device board 10 and supplies a driving signal to the gate line so as to drive the organic transistor 10a. The external connection part 35 is provided only on one side of the substrate 20.

Referring to FIG. 1B, the organic transistor 10a and the outer periphery 10b of the electro-optical device board 10 will now be described. As shown in FIG. 1B, the organic transistor 10a has a structure including source and drain electrodes (lower electrodes) 30, a semiconductor layer 31, an insulating layer 32, the gate electrode (second connection wiring) 34, and a protective film 40 on the substrate 20. The pixel electrode D (shown in FIG. 1A) is provided corresponding to the organic transistor 10a, and is coupled to the drain electrode via a contact hole. The pixel electrode D may be an extension from the drain electrode 30. A display medium responding to a voltage change can be driven through the insulating layer 32 and the protective film 40. The outer periphery 10b has a structure including the external connection part 35, the insulating layer 32, the gate line 34a, the gate line connection part 34b, and the gate line lead 34c. In the outer periphery 10b, the insulating layer 32 has a step 32a. The gate line 34a is provided along the step 32a so as to cover from the surface of the insulating layer 32 to the surface of the gate line connection part 34b. Accordingly, the gate line 34a electrically couples the gate electrode 34 to the gate line connection part 34b. Moreover, the external connection part 35 is coupled to the FPC 50.

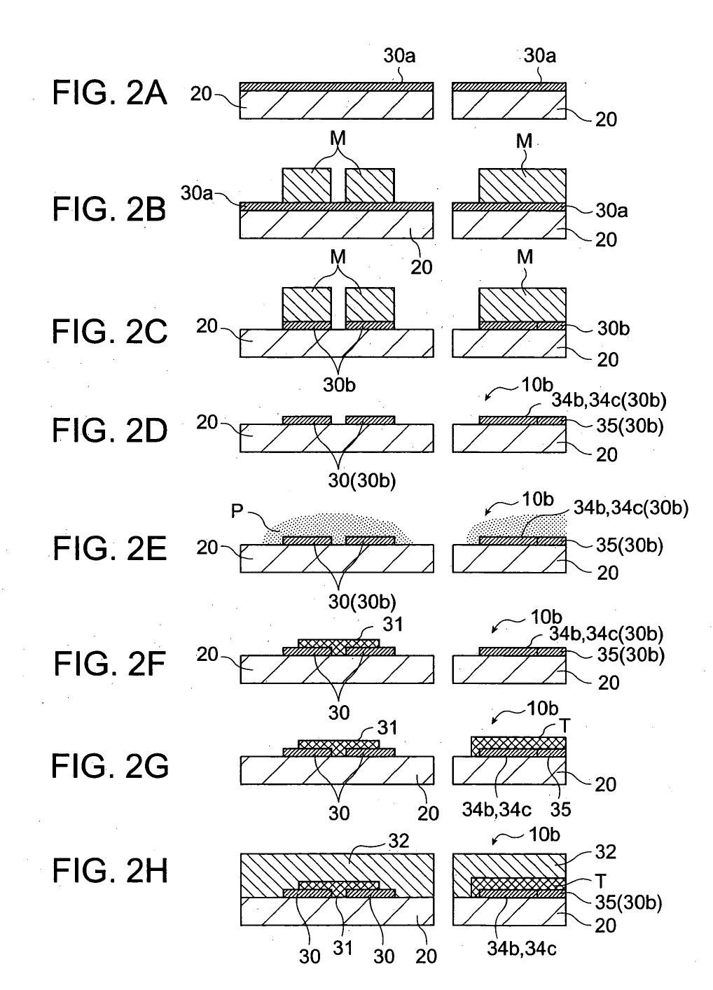

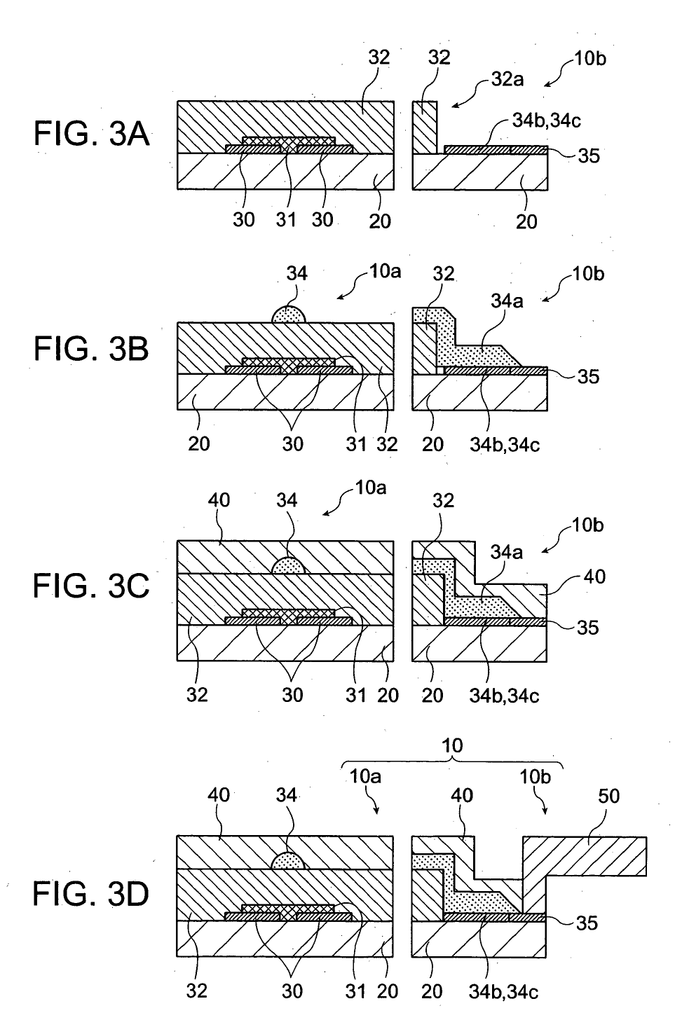

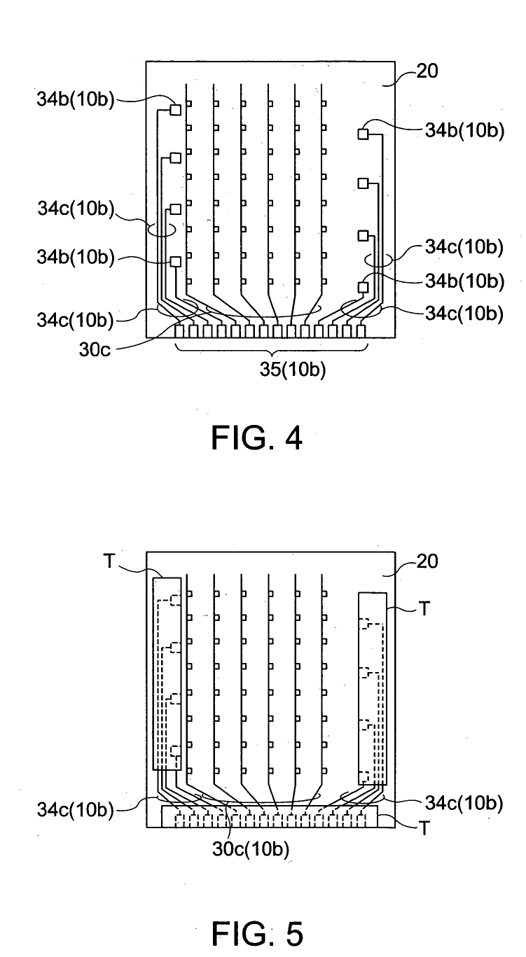

Referring to FIGS. 2 through 6, a method for manufacturing the electro-optical device board 10, and each element of the electro-optical device board 10 will now be described. FIGS. 2 through 6 illustrate the steps of a method for manufacturing the electro-optical device board 10. FIGS. 2 and 3 are sectional views of the organic transistor 10a and the outer periphery 10b shown in FIG. 1B. FIGS. 4 through 6 are plane views of the electro-optical device board 10 shown in FIG. 1A.

As shown in FIG. 2A, the substrate 20 made of plastic is thoroughly washed and compressed. Then, a metal film 30a is deposited or sputtered on the entire surface of the substrate 20. The thickness of the metal film 30a is preferably from 30 to 300 nm. The metal film 30a may be made of various highly conductive materials. If high light transmittance is required, ITO, ZuO₂, or the like is used. If an organic semiconductor, which will be described later, operates as a P-channel, materials such as Au, Pt, Pd, Ni, Cu, and Ag can be effectively used as the metal film. In the present embodiment, Au is used to make the metal film. In this example, a chromium or titanium film may be formed to a thickness of 1 to 20 μm between the substrate 20 and the metal film 30a in order to increase adhesion between the metal film 30a and the substrate 20.

As shown in FIG. 2B, a photoresist is applied on the entire surface of the metal film 30a, and is hardened by heat treatment. Then, exposure and development treatment are performed to form a mask M. Next, as shown in FIG. 2C, etching is performed via the mask M so as to form a metal film pattern 30b in accordance with the opening pattern of the mask M. Subsequently, as shown in FIG. 2D, the mask M is removed, and thus only the metal film pattern 30b remains on the substrate 20. Here, the metal film pattern 30b includes not only the source and drain electrodes 30 of the organic transistor 10a, but also the gate line connection part 34b, the gate line lead 34c, the external connection part 35, and the source line lead 30c making up the outer periphery 10b (see FIG. 4). If the pixel electrode D is an extension from the drain electrode 30, the pattern also includes the pixel electrode.

As shown in FIGS. 2A through 2D, the source and drain electrodes 30 and the outer periphery 10b are formed at the same time by photolithography, and the pattern in accordance with the opening pattern of the mask M is provided. Therefore, for example, it is possible to form highly fine wiring patterns of the gate line lead 34c. As the highly fine wiring patterns are available, the gate line lead 34c is provided aggregately on one side of the substrate 20 to form the external connection part 35.

Compared to ink jetting, photolithography provides finer line widths in manufacturing the outer periphery 10b. As a practical matter, ink jetting can provide, a line width and line width pitch of at least 30 μm. For example, if 100 wirings are formed by ink jetting, a line width of at least 6000 μm ((30 μm+30 μm)·100 wirings) is required. With such a width, however, a compact display cannot be provided. Meanwhile, the present embodiment makes it easy to provide a line width of 10 μm or less, and even of 6 μm or less, by employing the photolithography method. For patterning the source and drain electrodes 30, the length and width of the channel are preferably 10 μm and 0.5 μm, respectively.

While the photolithography method for patterning involves exposure to light in the present embodiment, other methods can also be used for this purpose. Other patterning methods involving exposure to light include a method for selectively developing a given film by preprocessing the substrate in forming a metal thin-film by electroless plating. More specifically, a method can be used for irradiating the substrate with ultraviolet rays via a mask to partly remove a catalyst required for electroless plating from the substrate. Also, a method for providing chemical processing to prevent such a catalyst from attaching to the substrate can be used.

A step for forming the semiconductor layer 31 on the source and drain electrodes 30 will now be described.

Since a material is applied to form the semiconductor layer 31 by liquid-phase processing, cleaning of the surface of the source and drain electrodes 30 is required at the molecular level prior to the liquid-phase processing. Therefore, the substrate 20 on which the source and drain electrodes 30 are formed is washed with water and an organic solvent, and surface treatment with oxygen plasma is carried out as shown in FIG. 2E. A typical method for carrying out this treatment with plasma involves generating plasma in a chamber, decreasing pressure in the chamber with a vacuum pump, and letting gases such as oxygen, nitrogen, argon, and hydrogen in the chamber. When atmospheric plasma is used instead of decreasing pressure, such a vacuum pump is not required.

After carrying out the treatment with oxygen plasma, the semiconductor layer 31 is formed by liquid-phase processing, represented by an inkjet (droplet discharge) method. In this instance, fluorene-bithiophene copolymer is used as the semiconductor layer 31. Fluorene-bithiophene is a conjugated polymer and has properties of semiconductor. It is dissolved by using an organic solvent, such as toluene, xylene, or trimethylbenzene. In this instance, the toluene, xylene, or trimethylbenzene solution of the conjugated polymer is discharged from the nozzle of an inkjet head as a droplet having a diameter of 10 to 50 μm. Then, the solution is locally applied over the source and drain electrodes 30 so as to bridge the electrodes. Next, the solution is dried at 60 to 80 degrees Celsius. The thickness of the semiconductor layer 31 is set in the range from approximately 10 to 150 nm. The thickness of the semiconductor layer 31 can be adjusted by the concentration of the solvent or polymer used. When the above-mentioned solvent is used, the above-mentioned thickness is available by setting the density of the solvent at 0.5 to 3.0% wt/vol. Examples of the material of the semiconductor layer 31 include low-molecular-weight organic semiconductor materials such as naphthalene, anthracene, tetracene, pentacene, hexacene, perylene, hydrazone, triphenylmethane, diphenylmethane, stilbene, aryl vinyl, pyrazoline, triphenylamine, triarylamine, oligothiophene, phthalocyanine and derivatives of these materials; and polymer organic semiconductor materials such as poly(N-vinylcarbazole), polyvinylpyrene, polyvinylanthracene, polythiophene, polyhexylthiophene, poly(p-phenylenevinylene), poly thienylene vinylene, polyarylamine, pyrene formaldehyde resin, ethylcarbazole formaldehyde resin, fluorene-bithiophene copolymer, fluorene-arylamine copolymer and derivatives of these materials. One or a combination of two or more of the above materials can be used. In certain implementations, a polymer organic semiconductor material can be used. The polymeric organic semiconductor materials can be formed as films by a simple process, and easily aligned. Among these materials, fluorene-bithiophene copolymer or polyarylamine may be used due to their high oxidation resistance and stability in the air.

As shown in FIG. 2G, the outer periphery 10b is provided with a masking tape T. An adhesive resin tape or the like is used as the masking tape T. While masking with the adhesive tape is used for exposing the outer periphery 10b in the present embodiment, other methods can be used instead. For example, instead of forming the insulating layer 32 by spin coating, the layer can be locally applied by ink jetting. In other words, the solution of an insulating material can be supplied to an inkjet head, discharged from its nozzle as droplets, and applied only to a position that requires an insulator. Since ink jetting can print patterns of 20 to 100 micrometers, it is possible to form an independent insulator for each thin-film transistor.

Another method employing an inkjet process includes dropping a solvent by ink jetting onto the insulating layer provided by spin coating, and thereby partly removing the insulating layer 32.

Another effective method is to remove the insulating layer 32 by spraying a solvent. This method provides high productivity while using a device that is simpler than a device used by the inkjet process. In order to limit an area in which droplets are sprayed, a slit aperture may be inserted between the spray nozzle and the device.

Another effective method is to perforate the insulating layer 32 by using a needle tool. If the insulating layer 32 is made of polymer, the substrate 20 is made of glass, and the external connection part 35 is made of metal, it is particularly easy to make a hole. This means that when the insulating layer 32 is not as hard as the substrate 20 and the external connection part 35, it is possible to partly peel off the insulating layer 32 by perforating or scratching the insulating layer 32 with a metal sending pin. Since the substrate is made of a hard material, the pin pressure may be controlled to the extent that the pin itself is not damaged. If the substrate 20 is made of plastic, it is necessary to control the pin pressure to avoid penetrating the external connection part 35. Controlling the pin can be easy if the external connection part 35 is substantially thick (200 nm or more). Therefore, it is beneficial to increase the thickness of the metal layer of the external connection part 35. The most suitable method for this purpose is electroless or electrolytic plating. In this instance, plating is carried out with only the external connection part 35 exposed. Otherwise, only the external connection part 35 is immersed in a plating solution. Thus, the thickness of the metal layer can be partly increased.

Alternatively, the insulating layer 32 provided by spin coating can be removed by being exposed to plasma. If the insulating layer 32 is made of polymer as described herein, the insulating layer 32 can be removed by placing the device in plasma in the presence of oxygen gas or of mixed gas of oxygen and CF₄.

As shown in FIG. 2H, an insulating polymer can be applied by spin coating to form the insulating layer 32. Polyvinylphenol or phenol resin (or novolac resin) can be used as the insulating polymer. Alternatively, acrylic resins including polymethylmethacrylate (PMMA), polycarbonate (PC), polystyrene, polyolefin, polyimide, and fluororesins can also be used. In the present embodiment, PMMA is used. A solution with a butyl acetate solvent is applied by spin coating to a thickness of 500 nm.

In this instance, in order to form the insulating layer 32 by applying such a solution, it is necessary to prevent the solvent contained in the solution of the insulating layer 32 from swelling or dissolving the semiconductor layer 31 and the substrate 20. Particular attention is required if the semiconductor layer 31 is soluble in the solvent. Since the semiconductor layer 31 is made up of conjugated molecules containing aromatic rings or conjugated polymers, it is soluble in aromatic hydrocarbons. Accordingly, hydrocarbons except for aromatic hydrocarbons or ketone, ether, and ester organic solvents are preferably used for applying the insulating layer 32. Furthermore, in some implementations, the insulating layer 32 can be insoluble in a liquid material of the gate electrode 34 that will be described later.

As shown in FIG. 3A, the masking tape T is peeled off to expose the outer periphery 10b. Thus, the step 32a is provided between the outer periphery 10b and the sidewall of the insulating layer 32. In this instance, to improve the absorption and the angle of contact of the gate electrode 34 and the gate line 34a, formed in a later step, an absorptive layer may be formed over the insulating layer 32.

As shown in FIG. 3B, a droplet of liquid material of the gate electrode 34 (gate line 34a) is formed on the insulating layer 32 to form the organic transistor 10a. The droplet of liquid material is discharged by an ink jetting process. In the inkjet process, a liquid material is discharged to a predetermined position on the insulating layer 32 by operating an inkjet head (not shown) and a moving mechanism (not shown) for moving the inkjet head relative to the substrate 20. The pattern of discharging the droplet of liquid material is determined by electronic data such as bitmap patterns stored in the droplet-discharge device. Therefore, the droplet liquid material is formed at a desired position by preparing such electronic data. Droplets are discharged from the inkjet head by either a piezoelectric method that changes the mass of an ink cavity by piezoelectric elements, or a thermal method that generates air bubbles by heating ink in an ink cavity. In order to discharge a droplet of liquid material with conductive, insulating, or semiconductor ink characteristics, a piezoelectric method that involves no heat effect can be employed.

A water dispersion of polyethylene dioxythiophene (PEDOT) can be used as the liquid material. Instead of PEDOT, metal colloid can also be used. While the main component of water dispersion is water, a liquid containing an alcohol additive can also be used as ink for inkjet printing. Moreover, the liquid material can be applied to cover a gap between the source and drain electrodes 30 (i.e. on the channel), and also can be applied to form the gate line 34a to couple a plurality of gate electrodes, each of which is the gate electrode 34. The gate line 34a is printed to be coupled to the external connection part 35. In this instance, using ink jetting, the ink jet head employed for discharge and the substrate 20 scan in a single direction for discharging in order to form the gate line 34a, which is a line extending in the X direction. Accordingly, the gate line 34a can be formed with minimum scanning (the minimum amount of travel).

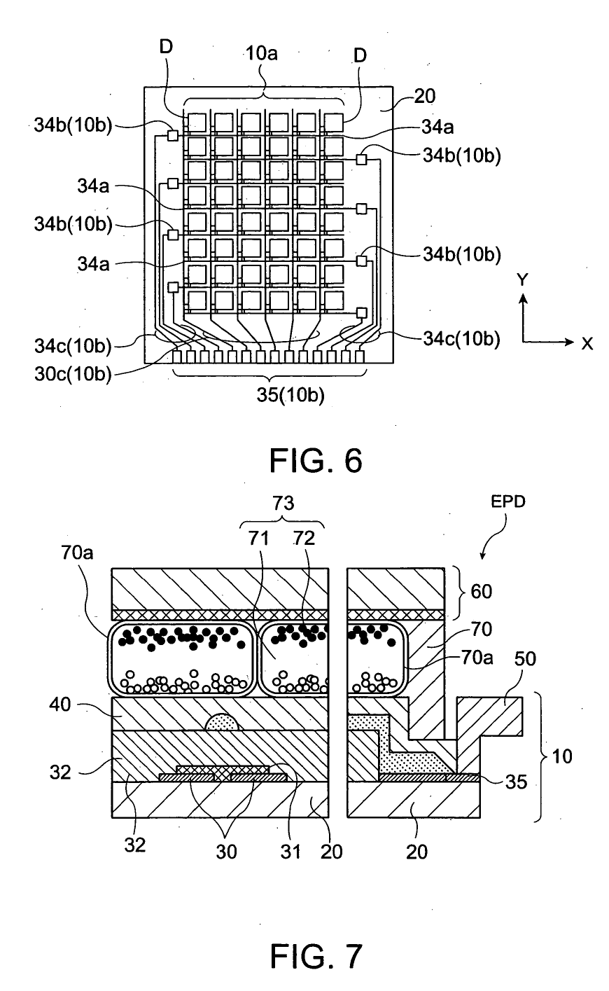

As shown in FIG. 3C, a polymer solution is spin coated so as to form the protective film 40. In this instance, by masking the external connection part 35 in advance, the protective film 40 is not provided to the external connection part 35. In addition, the pixel electrode D may be formed corresponding to the organic transistor 10a, for example as shown in FIG. 6. Also, if it is necessary to pass current in a display medium such as an organic light-emitting diode, the pixel electrode may be formed on the protective film so as to couple the pixel electrode to the organic transistor via a contact hole.

As shown in FIG. 3D, the external connection part 35 is coupled to the FPC 50, which completes the electro-optical device board 10. In this instance, an anisotropic conductive film or paste can be used for coupling the FPC 50 to the external connection part 35.

As described above, the organic transistor 10a, the gate line connection part 34b, the gate line lead 34c, the source line lead 30c, and the external connection part 35 can be formed simultaneously by photolithography in the present embodiment. Therefore, it is possible to provide highly fine patterns with a simplified process. In addition, the highly fine patterns can be easily aggregated on one side of the substrate 20. Also, forming the gate line 34a by ink jetting allows patterning directly on the substrate 20. Therefore, film-forming and removal steps, which are involved in photolithography, are not required, and thus the patterning can be provided more easily.

Moreover, forming the gate line 34a by ink jetting does not impose a heat load on the substrate 20 and polymer materials. In the series of steps for forming the organic transistor 10a and the outer periphery 10b, it is possible to minimize the steps that cause a heat load on the substrate 20, for example, the film-forming step. Accordingly, if the substrate 20 is made of a plastic material, the risk of thermal expansion, buckling, and other deformation of the substrate caused by such a heat load can be reduced. In other words, the present method for manufacturing the electro-optical device board 10 can achieve low-cost, low-temperature, and low-energy manufacturing. The method can be used for manufacturing a flexible device.

The source and drain electrodes 30, the gate line connection part 34b, the gate line lead 34c, the source line lead 30c, the external connection part 35, and the pixel electrode D can be formed simultaneously on the substrate 20 in the organic transistor 10a, and thereby can achieve the above-mentioned effects.

Also, since the gate line connection part 34b, the gate line lead 34c, the source line lead 30c, and the external connection part 35 can be formed by photolithography, they can be easily aggregated. In other words, while using ink jetting can result in decreased productivity due to limited patterning resolution and multiple scans by an inkjet head, using photolithography can solve these problems. Also, since the FPC 50 is coupled to the external connection part 35 aggregated on one side of the substrate 20, the FPC 50 does not need to be formed on both sides. This increases the layout flexibility of an electronic device having the electro-optical device board 10.

While the method for manufacturing a top-gate organic transistor has been described in the above-mentioned embodiment, it is also possible to apply the present invention to a bottom-gate organic transistor. The bottom-gate structure includes a gate electrode as a lower electrode. On the gate electrode, source and drain electrodes are formed with an insulating layer therebetween. In the bottom-gate structure, the gate electrode and the outer periphery 10b can be formed by photolithography, in the manner described above. Meanwhile, the source and drain electrodes are formed by ink jetting, as mentioned above.

While the structure mentioned above can be coupled to a driving circuit via the FPC, it also can be mounted to an integrated circuit chip directly on the substrate 20 for a driving circuit. In this case, a coupling terminal of the integrated circuit can be placed face to face with the external connection part 35, and bonded by soldering, or using an anisotropic conductive paste or film.

Referring now to FIG. 7, an electrophoretic display will be described as an example of electro-optical devices having the electro-optical device board.

As shown in FIG. 7, an opposing substrate 60 is placed face to face with the electro-optical device board 10, and an electrophoretic layer (electro-optical layer) 70 is placed between the board 10 and the substrate 60 to form an electrophoretic display EPD.

In this instance, the electrophoretic layer 70 includes a plurality of microcapsules 70a. Each of the microcapsules 70a is made of a resin film, and is as large as a pixel. The plurality of microcapsules 70a can be provided to cover the entire display area. More specifically, neighboring microcapsules 70a are located close to each other, so that the display area is covered by the microcapsules 70a leaving no space between the microcapsules. Each of the microcapsules 70a contains an electrophoretic dispersion liquid 73 having a dispersion medium 71, an electrophoretic particle 72, etc.

The electrophoretic dispersion liquid 73 having the dispersion medium 71 and the electrophoretic particle 72 will now be described in greater detail. In the electrophoretic dispersion liquid 73, the electrophoretic particle 72 is dispersed in the dispersion medium 71 stained with a dye. The electrophoretic particle 72 is a substantially spherical, fine particle whose diameter is about 0.01 to 10 μm. The electrophoretic particle 72 is made of an inorganic oxide or inorganic hydroxide having a hue (including black and white) different from the hue of the dispersion medium 71. As such, the electrophoretic particle 72 made of an inorganic oxide or inorganic hydroxide has an intrinsic surface isoelectric point. The surface charge density (i.e. the amount of charge) of the electrophoretic particle 72 varies in proportion to the hydrogen-ion exponent pH of the dispersion medium 71.

In this instance, the surface isoelectric point is in a state where the algebraic sum of ampholyte charge in the solution is zero, represented by the hydrogen-ion exponent pH. For example, if the pH of the dispersion medium 71 is equal to the surface isoelectric point of the electrophoretic particle 72, the effective charge of the particle is zero, and the particle does not respond to external electrolysis. If the pH of the dispersion medium 71 is less than the surface isoelectric point of the particle, the surface of the particle becomes positively charged in accordance with formula (1) below. On the other hand, if the pH of the dispersion medium 71 is greater than the surface isoelectric point of the particle, the surface of the particle becomes negatively charged in accordance with formula (2) below.
pH low: M−OH+H⁺(excess)+OH⁻→M−OH₂⁺+OH⁻ (1)
pH high: M−OH+H⁺+OH⁻(excess)→M−OH⁻+H⁺ (2)

As the difference between the pH of the dispersion medium 71 and the surface isoelectric point of the particle increases, the amount of charge of the particle increases according to formula (1) or (2). When the difference exceeds a certain level, the amount of charge is nearly saturated and neither increases nor decreases even if the pH changes further. Although this level varies depending on the type, size, shape, etc. of the particle, the amount of charge is considered to be nearly saturated when the difference reaches a value of about 1 or more for any particle.

The electrophoretic particle 72 can be, for example, titanium dioxide, zinc oxide, magnesium oxide, colcothar, aluminum oxide, black lower titanium oxide, chromium oxide, boehmite, FeOOH, silicon dioxide, magnesium hydroxide, nickel hydroxide, zirconium oxide, and copper oxide.

The electrophoretic particle 72 can be used as a plain particle, or with its surface modified in various ways. For example, the surface of the particle can be coated with acrylic resin, epoxy resin, polyester resin, polyurethane resin, and other polymers; coupled with silane, titanate, aluminate, fluorine, and other coupling agents; and graft polymerized with acrylic monomer, styrene monomer, epoxy monomer, isocyanate monomer, and other monomers. For the surface of the particle, one or a combination of two or more of the above-mentioned processing methods can be performed.

Non-aqueous organic solvents such as hydrocarbon, halogen hydrocarbon, and ether can be used as the dispersion medium 71. The dispersion medium 71 can be stained with a dye, such as spirit black, oil yellow, oil blue, oil green, Bali first blue, macrorex blue, oil brown, Sudan black, and first orange. The dispersion medium 71 has a hue different from the electrophoretic particle 72.

The electrophoretic display having the above-mentioned structure includes the electro-optical device board 10. Therefore, it can be manufactured at low cost, low temperature, and low energy. Furthermore, it provides a flexible display.

The electrophoretic display can be used with various electronic equipment having a display. Examples of electronic equipment having the electrophoretic display will now be described.

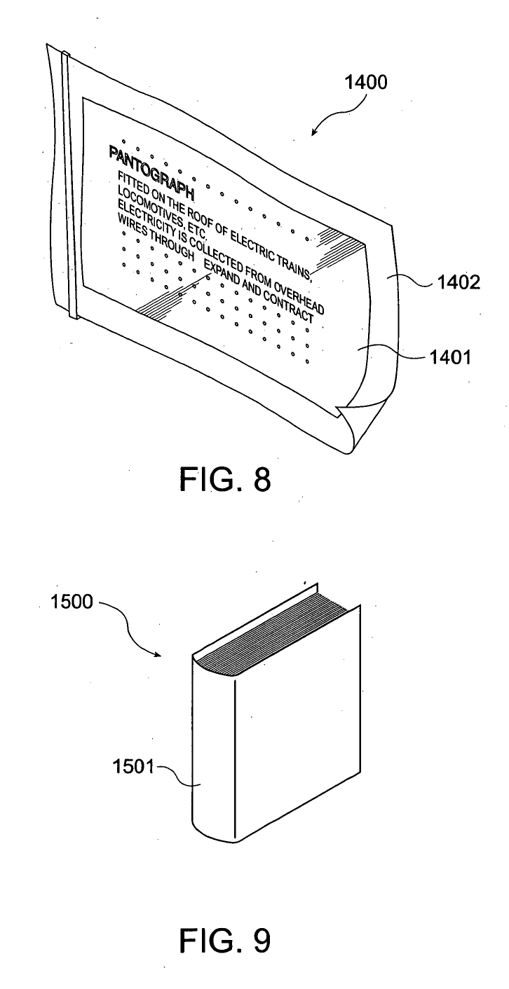

Firstly, an example in which the electrophoretic display is applied to flexible electronic paper will be explained. FIG. 8 is a perspective view showing the structure of such electronic paper. Electronic paper 1400 uses the electrophoretic display of the present invention as a display 1401. The electronic paper 1400 also has a body 1402 formed of a rewritable sheet having the same texture and flexibility as conventional paper.

FIG. 9 is a perspective view showing the structure of an electronic notebook 1500. An electronic notebook 1500 includes a bundle of sheets of the electronic paper 1400 shown in FIG. 8. A cover 1501 holds the electronic paper 1400. The cover 1501 includes data input means (not shown) for inputting display data sent from an external device, for example. The content displayed on the electronic paper is changed and renewed in accordance with the display data, while the electronic paper is being bundled.

In addition to the above-mentioned example, other electronic equipment having a display in which an electrophoretic display can be used include, but are not limited to, liquid crystal televisions, video tape recorders of viewfinder types or monitor viewing types, car navigation devices, pagers, personal digital assistants, electric calculators, word processors, work stations, picture phones, point-of-sale terminals, and apparatuses equipped with a touch panel. The electro-optical device according to the present invention can also be used as a display for these electronic equipment.

It should be understood that the above-mentioned embodiments and examples are not intended to limit the present invention. Various changes and modifications can be made without departing from the spirit and scope of the present invention.

1. A method for manufacturing an electro-optical device board including on a substrate a plurality of switching elements and a plurality of wirings coupled to the plurality of switching elements, comprising:
forming at least one of the switching elements and a first wiring simultaneously by patterning using light irradiation; and
forming a second wiring by an additive patterning process

2. The method for manufacturing an electro-optical device board according to claim 1, wherein the patterning using light irradiation involves a photolithography process.

3. The method for manufacturing an electro-optical device board according to claim 1, wherein the additive patterning process is a liquid-discharge or mask-deposition process.

4. The method for manufacturing an electro-optical device board according to claim 1, wherein a lower electrode of the switching element and the first wiring are formed simultaneously.

5. The method for manufacturing an electro-optical device board according to claim 1, wherein the second wiring and a gate electrode of the switching element are formed simultaneously.

6. The method for manufacturing an electro-optical device board according to claim 4, wherein the lower electrode includes source and drain electrodes.

7. The method for manufacturing an electro-optical device board according to claim 1, wherein each of the switching elements includes an organic semiconductor layer.

8. The method for-manufacturing an electro-optical device board according to claim 7, wherein the organic semiconductor layer is a polymer mainly containing arylamine.

9. The method for manufacturing an electro-optical device board according to claim 7, wherein the organic semiconductor layer is composed of a copolymer mainly containing fluorene-bithiophene.

10. The method for manufacturing an electro-optical device board according to claim 7, wherein the organic semiconductor layer is formed by an inkjet process.

11. The method for manufacturing an electro-optical device board according to claim 1, wherein the plurality of first wirings are aggregated on one side of the substrate.

12. The method for manufacturing an electro-optical device board according to claim 1 1, wherein each of the first wiring are coupled to an integrated circuit.

13. The method for manufacturing an electro-optical device board according to claim 1, wherein widths of the first and second wirings and a gap between the first and second wirings are less than or equal to 10 μm.

14. The method for manufacturing an electro-optical device board according to claim 1, wherein widths of the first and second wirings and a gap between the first and second wirings are less than or equal to 6 μm.

15. The method for manufacturing an electro-optical device board according to claim 1, wherein the substrate is a plastic substrate.

16. An electro-optical device board manufactured by the manufacturing method according to claim 1.

17. An electro-optical device, comprising:
an electro-optical device board including on a substrate a plurality of switching elements and a plurality of wirings coupled to the plurality of switching elements, the electro-optical device board manufactured by a method including the steps of,
forming one of the plurality of switching elements and a first wiring simultaneously by patterning using light irradiation; and
forming a second wiring by a patterning process;
an opposing substrate placed face to face with the electro-optical device board; and
an electro-optical layer provided between the electro-optical device board and the opposing substrate.

18. Electronic equipment comprising the electro-optical device according to claim 17.
